(19) United States
(12) Patent Application Publication
(10) Pub. No.: US 2026/0051803 A1
(43) Pub. Date: Feb. 19, 2026

(54) SYSTEM AND METHODS FOR GAN LOSSLESS CURRENT SENSING USED IN MOTOR DRIVE CIRCUITS

(71) Applicant: Navitas Semiconductor Limited, Dublin (IE)

(72) Inventors: Victor SINOW, Fresno, CA (US); Ren Huei TZENG, Redondo Beach, CA (US); Marco GIANDALIA, Marina Del Rey, CA (US)

(73) Assignee: Navitas Semiconductor Limited, Dublin (IE)

(21) Appl. No.: 19/298,908

(22) Filed: Aug. 13, 2025

Related U.S. Application Data
(60) Provisional application No. 63/683,945, filed on Aug. 16, 2024.

(51) Int. Cl. H02M 1/00; H02M 1/32; H03K 19/003

(52) U.S. Cl. CPC H02M 1/0009; H02M 1/0054; H02M 1/32; H03K 19/00315

(57) ABSTRACT

A circuit is disclosed. The circuit includes a first switch having a first source terminal and first drain terminal, a second switch having a second source terminal and second drain terminal, the second drain terminal connected to the first drain terminal and the second source terminal connected to the first source terminal. In one aspect the second switch is arranged to generate a first signal corresponding to a current flowing from the first source terminal to the first drain terminal. In another aspect, a sensing circuit is arranged to receive the first signal and to determine a magnitude and polarity of the current flowing from the first source terminal to the first drain terminal, the sensing circuit further arranged to transmit a second signal based on the first signal.

### CROSS REFERENCE TO RELATED APPLICATIONS

This application claims priority to U.S. provisional patent application No. 63/683,945, for “SYSTEM AND METHODS FOR GAN LOSSLESS CURRENT SENSING USED IN MOTOR DRIVE CIRCUITS” filed on Aug. 16, 2024, which is hereby incorporated by reference in entirety for all purposes.

### FIELD

The described embodiments relate generally to power converters, and more particularly, the present embodiments relate to systems and methods for gallium nitride (GaN) lossless current sensing used in motor drive circuits.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. As many electronic devices are sensitive to size and efficiency of the power conversion circuit, new power converters can provide relatively higher efficiency and lower size for the new electronic devices.

### SUMMARY

In some embodiments, a circuit is disclosed. The circuit includes a first switch having a first source terminal and first drain terminal; a second switch having a second source terminal and second drain terminal, the second drain terminal connected to the first drain terminal and the second source terminal connected to the first source terminal, where the second switch is arranged to generate a first signal corresponding to a current flowing from the first source terminal to the first drain terminal; and a sensing circuit arranged to receive the first signal and to determine a magnitude and polarity of the current flowing from the first source terminal to the first drain terminal, the sensing circuit further arranged to transmit a second signal based on the first signal.

In some embodiments, the first switch is a gallium nitride (GaN)-based switch.

In some embodiments, the second switch is a GaN-based switch.

In some embodiments, the first and second switches are monolithically formed on single die.

In some embodiments, the circuit further includes a third switch having a third source terminal and a third drain terminal, the third source terminal connected to the first drain terminal and to a first terminal of a load, and the third drain terminal connected to a power input node.

In some embodiments, the circuit further includes a fourth switch having a fourth source terminal and a fourth drain terminal, the fourth drain terminal connected to the third drain terminal and the fourth source terminal connected to the third source terminal.

In some embodiments, the load is a motor.

In some embodiments, the first switch and the second switch are formed on a gallium nitride (GaN)-based die and the sensing circuit is formed on a silicon-based die, where the GaN-based die and the silicon-based die are co-packaged in a unitary semiconductor die.

In some embodiments, the circuit further includes an overcurrent protection circuit arranged to receive the second signal, compare the second signal to a first threshold and generate a turn off signal when the second signal exceeds the first threshold.

In some embodiments, a level shifting circuit is disclosed. The level shifting circuit includes a transmit circuit; a receive circuit; and a first level shifting switch and a second level shifting switch; where the transmit circuit is formed on a first silicon-based die, the receive circuit is formed on a second silicon-based die, and the first and second level shifting switches are formed on a gallium nitride (GaN)-based die.

In some embodiments, the first and second silicon-based die and the GaN-based die are co-packaged in a unitary semiconductor package.

In some embodiments, a source terminal of the first level shifting switch is connected to a source terminal of the second level shifting switch and to a current source.

In some embodiments, the current source is disposed on the first silicon-based die.

In some embodiments, the level shifting circuit further includes a common mode feedback circuit.

In some embodiments, during manufacturing the first and second silicon-based die are disposed adjacent on a silicon wafer, where the first and second silicon-based die are picked and co-packaged together in the unitary semiconductor package.

In some embodiments, a method of operating a circuit is disclosed. The method includes providing a first switch having a first source terminal and first drain terminal; providing a second switch having a second source terminal and second drain terminal, the second drain terminal connected to the first drain terminal and the second source terminal connected to the first source terminal; generating, by the second switch, a first signal corresponding to a current flowing from the first source terminal to the first drain terminal; and receiving, by a sensing circuit, the first signal; and determining, by the sense circuit, a magnitude and polarity of the current flowing from the first source terminal to the first drain terminal; and transmitting, by the sense circuit, a second signal based on the first signal.

In some embodiments of the disclosed method, the first and second switches are gallium nitride (GaN)-based switches, where the first and second switches are monolithically formed on single die.

In some embodiments, the method further includes providing a third switch having a third source terminal and a third drain terminal, the third source terminal connected to the first drain terminal and to a first terminal of a load, and the third drain terminal connected to a power input node.

In some embodiments, the method further includes proving a fourth switch having a fourth source terminal and a fourth drain terminal, the fourth drain terminal connected to the third drain terminal and the fourth source terminal connected to the third source terminal.

In some embodiments, the method further includes receiving, by an overcurrent protection circuit, the second signal and comparing the second signal to a first threshold and generating a turn off signal when the second signal exceeds the first threshold.

### BRIEF DESCRIPTION OF THE DRAWINGS

FIG. 1 illustrates a simplified schematic of an integrated power device with bidirectional current sensing, according to certain embodiments;

FIG. 2 illustrates use of an external resistor for sensing the current through a power switch by an internal bi-directional current amplifier, according to some embodiments;

FIG. 3 illustrates a system level schematic of a power converter having a controller and an integrated power device, according to certain embodiments;

FIG. 4 illustrates a graph showing timing diagram of voltages at various nodes within the circuit of FIG. 3;

FIG. 5 illustrates a simplified schematic of an integrated power device with bidirectional external current sensing circuit using internal current sense amplifier of the integrated GaN-based die of FIG. 1, according to some embodiments;

FIG. 6 is a simplified flowchart illustrating a method for the activation of the synchronous rectification (SR) functionality;

FIG. 7 and FIG. 8 illustrate graphs showing timing diagrams of SR turn on and SR turn off, according to some embodiments;

FIG. 9 is a simplified flowchart illustrating a method for turning off the power switch early in the SR mode, according to some embodiments; and

FIG. 10 illustrates a simplified schematic of a level shifter system, according to certain embodiments.

### DETAILED DESCRIPTION

Circuits, devices and related techniques disclosed herein relate generally to power converters. More specifically, systems, circuits, devices and related techniques disclosed herein relate to GaN power switches having lossless current sensing that are used in motor drive half-bridge and full-bridge applications. In some embodiments, an integrated power device can include a GaN power switch along with integrated bidirectional lossless current sensing that can eliminate use of external current sensing resistors, thereby increasing system efficiency. The integrated bidirectional lossless current sensing can also enable the integrated power device to autonomously turn on the GaN power switch during the third quadrant conduction, thus increasing system efficiency further. The integrated power device with bidirectional lossless current sensing can enable sensing of a magnitude and direction of a current flowing through the GaN power switch in positive (i.e., from the drain to source) and negative (i.e., from the source to drain) directions. The sensed magnitude and direction of the current can be transmitted to a driver and/or a controller circuit, where the driver/controller circuit can control a conductivity state of the GaN power switch autonomously in response to receiving the sensed magnitude and direction of the current.

In some embodiments, the integrated power device can include sense and drive circuits co-packaged with a GaN power switch within a unitary semiconductor package. The sense and drive circuits may include a differential amplifier circuit arranged to detect magnitude and positive and/or negative direction of a current flowing through the GaN power switch. In various embodiments, an external resistor may be used for sensing of the current flowing through the GaN power switch. Embodiments of the disclosure enable the use of sense and drive circuits to amplify the voltage across the external sense resistor. Utilizing the internal sense circuits can allow for use of an external resistor have a value that is relatively small as compared to the external resistor values used in current approaches, because disclosed circuits and techniques can detect the magnitude and direction of the current flowing through the GaN power switch based on a relatively small voltage developed across the external resistor. In this way, the converter power loss can be minimized. In some embodiments, the external resistor may have a value of, for example, 5 to 10 times smaller than resistor values used in current approaches.

Motor drive applications may require relatively accurate sensing of the current through the power switch. These motor drive applications can include, but are not limited to, washing machines, dryers or hair dryer applications. Circuits and techniques disclosed herein enable relatively accurate sensing of a current through a power switch, where the accuracy of the sensed current can be maintained with relatively high level of precision over the life of an appliance. In some embodiments, a relatively small switch may be coupled to the power switch where the small switch is arranged to sense a current flowing through the power switch. Circuits and techniques disclosed herein enable mitigating effects of variations over time of a ratio of the current in the main switch to the small switch. For example, a ratio of a current through the main switch to the current through the small switch may vary up to 7% over time. In motor drive applications, it is beneficial to have the ratio stay relatively constant over time. Embodiments of the disclosure enable relatively accurate current sensing over time. Furthermore, embodiments of the disclosure enable bidirectional sensing of the current through of the power switch. Thus, circuits and techniques disclosed herein enable bidirectional current sensing using the small switch and/or using an external resistor for sensing of the current.

In some embodiments, control methods for autonomous synchronous rectifier (SR) mode enable the power switch to operate as an ideal diode or have reverse channel conduction when the current through the switch is negative (i.e., flowing from the source to the drain). In motor inverter and other applications where reverse current can flow through the power switches, also called “freewheeling”, the voltage across the power switch in combination with the reverse current may create relatively high power dissipation. Circuits and techniques disclosed herein enable driving the power switch as a synchronous rectifier. In some embodiments, upon detection of significant reverse current in the power switch, the power switch may be turned on, thereby reducing power losses when current flows from the source to the drain. Further, upon approaching zero current (SROFF) the switch can be turned off, autonomously and without use of a controller.

In various embodiments, methods for autonomous synchronous rectifier (SR) mode in half-bridge circuits can include turn-off intervention modes. In these embodiments, the power switch may turn-off early in SR mode.

Circuits and techniques disclosed herein can enable lossless current sensing in multi-phase motor driver circuits, for example, 3-phase motor drive circuits. In some embodiments, the sensed current for each phase may be arranged in a wired-OR configuration. In various embodiments, the IC may include positive and negative dV/dt control circuits. In some embodiments, the dV/dt control circuits may include external and/or internal impedance elements coupled to the input pins of the IC. In various embodiments, the driver IC may include gate overdrive circuits. The gate overdrive circuits are disclosed in U.S. patent application Ser. No. 18/733,480, which is incorporated herein by reference. In various embodiments, circuits and methods disclosed herein are suitable for driving or controlling GaN based power switches, silicon based and/or silicon carbide-based switches.

In some embodiments, a level shifting circuit may include a silicon-based transmit circuit, GaN-based level shifting switches and a silicon-based receive circuit. In various embodiments, during the manufacturing process the silicon-based transmit circuit and the silicon-based receive circuit may be picked from adjacent locations on a silicon wafer to ensure relatively high matching between the transmit die and the receive die. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

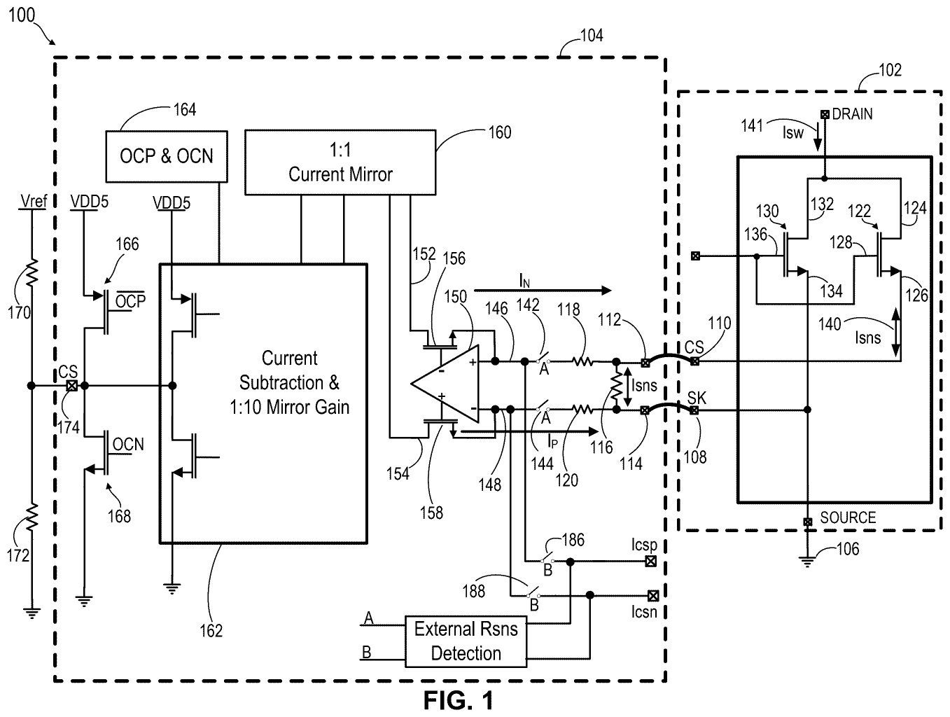

FIG. 1 illustrates a schematic of an integrated power device with bidirectional current sensing circuits, according to some embodiments. FIG. 1 shows a schematic of an integrated power device 100 that can include a gallium nitride (GaN)-based die 102 co-packaged with a silicon-based die 104 in a unitary semiconductor package. The GaN-based die 102 can include one or more GaN-based power switches. The silicon-based die 104 can include current sensing circuits. In some embodiments, the silicon-based die may include additional circuits such as, but not limited to, driver and controller circuits. The integrated power device may also be referred to as an electronic device.

In the illustrated embodiment, the GaN-based die 102 may include a GaN power switch 130 having a drain terminal 132, a gate terminal 136 and a source terminal 134. The GaN-based die 102 may further include a GaN switch 122 having a drain terminal 124, a gate terminal 128 and a source terminal 126. The drain terminal 132 may be connected to the drain terminal 124 and the gate terminal 136 may be connected to the gate terminal 128. In some embodiments, the GaN switch 122 may be relatively small. The source terminal 134 can be connected to a ground 106. The source terminal 134 can also be connected to a kelvin terminal 108. The source terminal 126 can be connected to an output terminal 110.

The GaN switch 122 can be arranged to sense a current flowing through the GaN power switch 130. A current 141 (Isw) can flow from the drain terminal 132 to the source terminal 134 of the GaN switch 130. A current 140 (Isns) can flow from the drain terminal 124 to the source terminal 126 of the GaN switch 122, where Isns can be generated based on Isw. In some embodiments, Isns can be proportional to Isw.

The silicon-based die 104 may include an input terminal 112 and input terminal 114. Input terminals 112 and 114 may be connected to output terminals 110 and 108, respectively. In some embodiments, input terminals 112 and 114 may be connected to output terminals 110 and 108 by wire bonds. The wire bonds may be a single wire bond or a plurality of wire bonds or any other techniques that can electrically form interconnection. A resistor 116 can be connected between the input terminals 112 and 114. In some embodiments, resistor 116 can have a value of, for example, 2000 Ω to 6000 Ω, while in other embodiments it can have a value of 4000 Ω. Input terminal 112 can also be connected to a resistor 118 and input terminal 114 can also be connected to a resistor 120. Resistor 118 may be connected to switch 142 and resistor 120 may be connected to switch 144. In some embodiments, resistor 118 can have a value of, for example, 396 Ω, while resistor 120 can have a value of, for example, 400 Ω.

Switch 142 can be connected to a first input terminal 146 of a current sense amplifier 150. Switch 144 can be connected to a second input terminal 148 of the current sense amplifier 150. In some embodiments, the current sense amplifier 150 can be arranged to operate bi-directionally. The current sense amplifier 150 can have a first output terminal 152 and a second output terminal 154. A switch 156 can be connected between the first output terminal 152 and the first input terminal 146 of the current sense amplifier 150. A switch 158 can be connected between the second output terminal 154 and the first input terminal 148 of the current sense amplifier 150.

An output of the current sense amplifier 150 can be a current output and can be indicative of the current flowing in the GaN power switch 130, either bi-directionally or uni-directionally. In some embodiments, the current sense amplifier 150 can sense the current through switch 122 enabling improved accuracy and lower lifetime drift. In various embodiments, the current sense amplifier 150 can sense a current flowing through an external sense resistor improved accuracy and lower lifetime drift. In some embodiments, over-current detection can be performed inside the silicon-based die IC 104. Embodiments of the disclosure enable a user to set their own over-current threshold in their micro-controller.

The output terminals of the current sense amplifier 150 can be connected to a current mirror circuit 160. In some embodiments, the current mirror 160 can be a 1:1 current mirror, i.e., a magnitude of the current entering the current mirror can be substantially equal to a magnitude of the current exiting the current mirror. The output terminals of the current mirror circuit 160 can be connected to the current mirror and subtraction circuit 162. In various embodiments, the current mirror and subtraction circuit 162 can be 1:10, i.e., a magnitude of the current entering the current mirror can be one tenth a magnitude of the current exiting the current mirror.

The current mirror and subtraction circuit 162 can be connected to an overcurrent detection circuit 164 that is arranged to generate an overcurrent positive signal (OCP) and an overcurrent negative signal (OCN) signal. The current mirror and subtraction circuit 162 can be connected to an output pin 174 (labeled CS). A switch 166 and a switch 168 can be connected to the CS pin as well. The CS pin can be connected to a resistor divider that is formed by serial connection of resistor 170 and resistor 172.

In some embodiments, integrated power device 100 can be formed in silicon, GaN or any other suitable semiconductor material. In various embodiments, both the sense circuits and the switches 130 and 122 can be formed in a silicon substrate. In some embodiments, both the sense circuits and the switches can be formed in a GaN substrate. In some embodiments, the sense circuit can be formed in a silicon substrate while the switches 130 and 122 can be formed in a GaN substrate. In various embodiments, both sense circuit and switches 130 and 122 can be monolithically integrated onto a single die. In some embodiments, the sense circuits and the switches can be formed on separate individual die. In various embodiments, the sense circuits and the switches 130 and 122 can be integrated into one electronic package, for example, but not limited to, into a quad-flat no-lead (QFN) package, or into a dual-flat no-leads (DFN) package, into a ball grid array (BGA) package. In some embodiments, the sense circuits and the switches can be individually packaged into an electronic package.

The current sense amplifier 150 can detect a value of Isw by detecting Isns. Isns can be generate a voltage across resistor 116. The generated voltage can be bi-directionally detected by the amplifier 150 and corresponding current signals I_{N} and I_{P} can be generated and transmitted to the current mirror circuit 160. In some embodiments, the current mirror circuit 160 can have a 1:1 ratio. The current mirror circuit 160 can transmit corresponding signals to the current mirror circuit 162, where the signals can be gained up. The current mirror circuit 162 can be arranged to drive the output pin 174 (labeled CS). In various embodiments, detection of an over-current condition can be performed internally to the integrated power device 100. In some embodiments, users can set their own OC threshold in their micro-controller.

An output stage of the current sense amplifier 150 can run current all the time, such that the output stage can always run a common-mode current. This enables a smooth and seamless transition from negative to positive sense voltage. In the disclosed bi-directional amplifier architecture, one side may run the differential current, depending on the polarity of the sense voltage. In some embodiments, resistor 120 can set the current in the output stage of the amplifier 150. In various embodiments, the sensing resistor 116 may have a value, for example, of 4 Ω. As an example, when the sensing resistor 116 has a value of 4 Ω and the resistor 120 has a value of 400 Ω, a resistor 118 can have a value of 396 Ω.

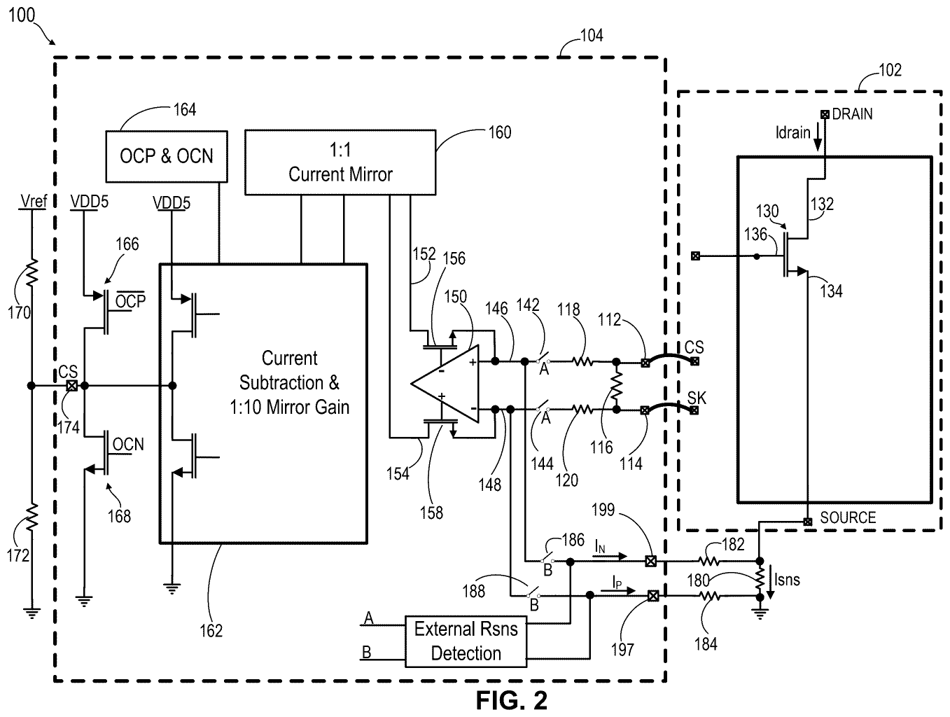

FIG. 2 illustrates use of an external resistor for sensing the current through the power switch by the internal bi-directional current amplifier, according to some embodiments. Utilizing the internal sensing circuits of the integrated power device 100 enables use of an external resistor that has a relatively small value as compared to the external resistor values used in current approaches, because of the relatively high sensitivity of the internal sensing circuits. In the illustrated embodiment, an external resistor 180 may be used to sense a current through the power switch 130. The external resistor 180 can be connected between the source terminal 134 and the ground.

The silicon-based die 104 can be connected to the external resistor 180 through resistor 182 and resistor 184. In some embodiments, switches 142 and 144 can be controlled by a signal A and the switches 186 and 188 can be controlled by a signal B. The current sense amplifier 150 can sense a current flowing through the external sense resistor 180 with improved accuracy and lower lifetime drift. The external resistor 180 may have a relatively small value, thereby resistors 182 and 184 can have similar values. Pins 199 (ICSP) and 197 (ICSN) can be floated when the internal current sense amplifier 150 is to be used. Below are example calculations for I_{N} and I_{P}:

$$When Isw > 0 :$$

$${I}_{P} = {I}_{SNS} \times \frac{4 Ω}{400 Ω} + {I}_{CM}$$

$${I}_{N} = {I}_{CM}$$

$$When Isw = 0 :$$

$${I}_{P} = {I}_{CM}$$

$${I}_{N} = {I}_{CM}$$

$$When Isw < 0 :$$

$${I}_{N} = {I}_{SNS} \times \frac{4 Ω}{400 Ω} + {I}_{CM}$$

$${I}_{P} = {I}_{CM}$$

In order to determine whether to use internal current sensing or external current sensing, the chip can force a current out of the ICSP and ICSN pins and when the voltage is greater than approximately 1.5V, then internal current sensing is used. A current value of, for example, 200 μA can be pulsed out of the ICSP and ICSN pins for a short time after part is enabled. During this determination time period (of internal or external current sensing decision), the amplifier can use internal current sensing. Internal current sensing using internal resistor 116 is used by default because it is connected all the time.

Once the determination has been performed on whether to use internal (resistor 116) or external current sensing (resistor 180), this determination is latched to prevent any changing of this determination while the chip is operating. This latch can be cleared when part turns off. In some embodiments, the latched data can only switch the input to the amplifier if the gate terminal 136 is low. This can prevent the amplifier from switching connections while gate terminal 136 is high. In various embodiments, during a first PWM pulse the current sensing can be performed internally, and subsequently current sensing can change to external current sensing starting on the next PWM pulse. This can only happen if PWM is high when enable goes high. In some embodiments, in order to use internal current sensing, ICSP and/or ICSN pins can be floated, or a capacitor or a relatively large resistor may be connected to ICSP and/or ICSN pins.

Now referring to the current mirror sections of the integrated power device 100, the current output at pin 174 (CS) may be gained up by, for example, by a factor of 10 from amplifier output current (for example, +/−2.5mA at Isw=+/−100%). A gain of the current mirror circuit 160 and a gain of the current mirror circuit 162 can be trimmed, to compensate for variations in ratio of the GaN power switch 130 to sensing switch 122. Offset trim can also be performed in the current mirror circuits 160 and 162, such that CS output current is zero when Isw=0.

The output stage can continuously run a current even when Isw=0, to improve response speed when the power switch current Isw passes through 0. For a bi-directional output, a user can place a resistor divider to a reference voltage or a single resistor to a reference voltage. CS pin voltage may stay within, for example, 0.5V to 3.5V for the output current to be relatively accurate. For a uni-directional output, a user can place a resistor from CS pin to GND (trim bit to configure for uni-directional output). In some embodiments, CS pin voltage is kept less than, for example, 3.5V for the output current to be relatively accurate. Positive and negative over-current detection can be performed internal to the integrated power device 100 and can sense current in the current mirror circuit. CS pin can be set to, for example, approximately 3.5V (or 5V), for a positive over-current and set to GND for a negative over-current.

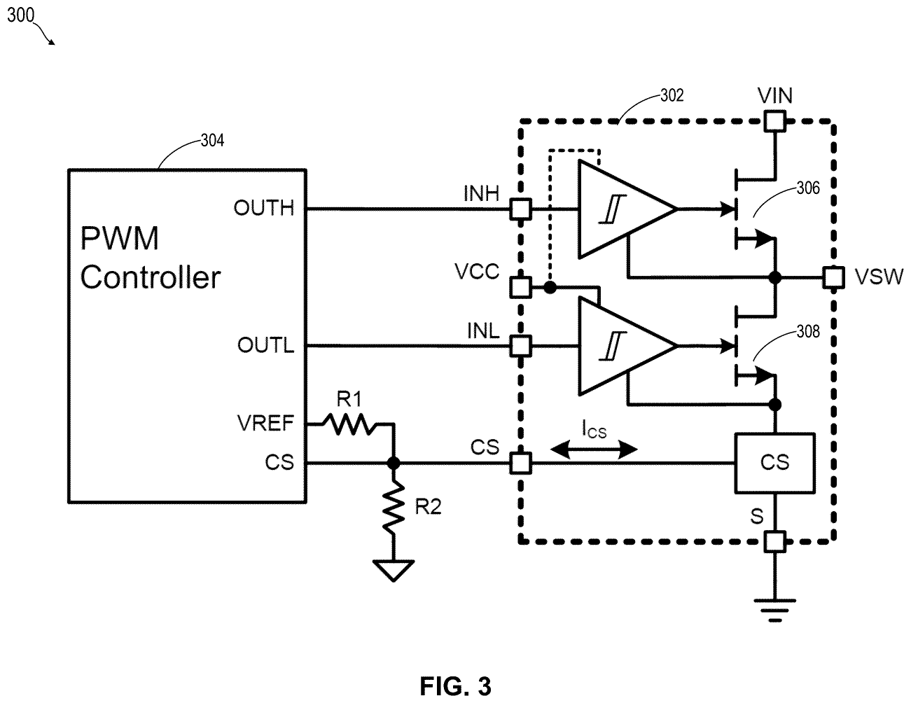

FIG. 3 illustrates a system level schematic of a power converter having a controller and an integrated power device, according to certain embodiments. Circuit 300 can include a controller 304 connected to an integrated power device 302. The integrated power device 302 is similar to the integrated power device 100 with the difference that integrated power device 302 includes two integrated power devices. The integrated GaN device 302 can be arranged to sense a magnitude and direction of a current flowing through the GaN power switch 308, in positive (i.e., from drain-to-source) or in negative (i.e., from source-to-drain) directions. In some embodiments, the integrated GaN device 302 can be arranged to sense a magnitude and direction of a current flowing through each of the GaN power switch 306 and 308, in positive (i.e., from drain-to-source) or in negative (i.e., from source-to-drain) directions.

In various embodiments, the GaN power switches may be formed on a GaN-based die and the sensing/driver circuits may be formed on a silicon-based die. The GaN-based die and the silicon-based die can be co-packaged in a unitary semiconductor package. In some embodiments, the GaN power switches and the sensing/driver circuits may be formed in a GaN-based die. In various embodiments, each of the GaN power switches may be coupled with a corresponding sensing circuit.

For many applications it can be useful to sense the cycle-by-cycle current flowing through the power switch. Current approaches for current sensing can include placing a sensing resistor between the source of the power switch and a ground. This method can increase system conduction power losses, creating hotspots on the PCB, and lowering overall system efficiency. To remove this external resistor and the associated hotspots, and to increase system efficiency, the integrated GaN device 302 can employ integrated bidirectional lossless current sensing techniques that are relatively accurate. In some embodiments, a current flowing through the internal low-side GaN power switch can be sensed internally and then converted to a current at the current sensing output pin (CS). An external resistor divider (R1, R2) may be connected to the CS pin and can be used to set the amplitude of the CS pin voltage signal. In this way, the CS pin signal can be enabled to work with different controllers with different current sensing input thresholds. In some embodiments, the resistor divider may be disposed relatively close to the CS pin for improved robustness and reduced system noise.

In some embodiments, the resistor divider can be driven by an external voltage, allowing it to set the midpoint voltage at an arbitrary level, e.g., to operate an A/D converter of the microcontroller at maximum resolution. Positive current through the GaN power FET can result in a current out of the CS pin, increasing the voltage at the midpoint of the resistor divider, and negative current through the GaN power FET can result in a current into the CS pin, reducing this voltage. The CS pin current may be a function of the gain factor and a magnitude of a current in the power transistor. The value of the resistor can be set such that a voltage range corresponding to full positive to full negative current can be adequately positioned within the ADC input voltage range, and the maximum voltage at the CS pin.

Embodiments of the disclosure can substantially reduce total on-resistance, R_{ON}(TOT), as compared to current approaches. For example, for a 300 W high-frequency boost PFC circuit, R_{ON}(TOT), may be reduced from 340 m ohm to 170 m ohm. The power loss savings by eliminating an external resistor can result in, for example, a +0.5% efficiency benefit for the overall system and elimination of the RCS PCB hotspot. Below equations show examples of calculations of gain and Vcs:

$$Internal Current Sense Amplifier Gain Ratio : \qquad Equation 1$$

$$Gain = I C S / IDS = 1.25 mA / 4.5 A = 0.2778 mA / A$$

$$Current Sense Pin Voltage - Internal Current Sensing \qquad Equation 2$$

$$V C S = R C S / 2 * Gain * IDS + V REF / 2$$

$$where R C S = R 1 = R 2 / 2$$

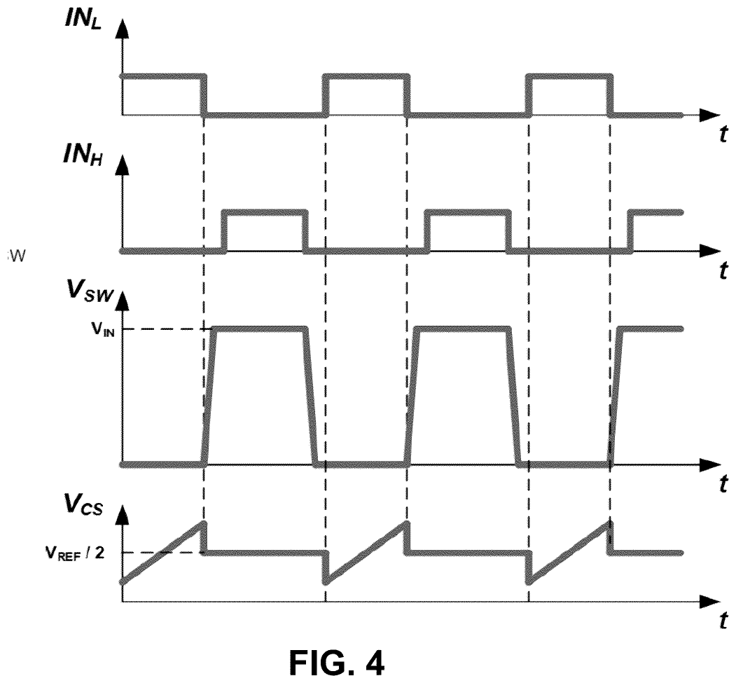

FIG. 4 illustrates a graph showing timing diagram of voltages at various nodes within the circuit of FIG. 3. FIG. 4 shows the voltage at IN_{L}, IN_{H}, V_{SW} and at the CS pin.

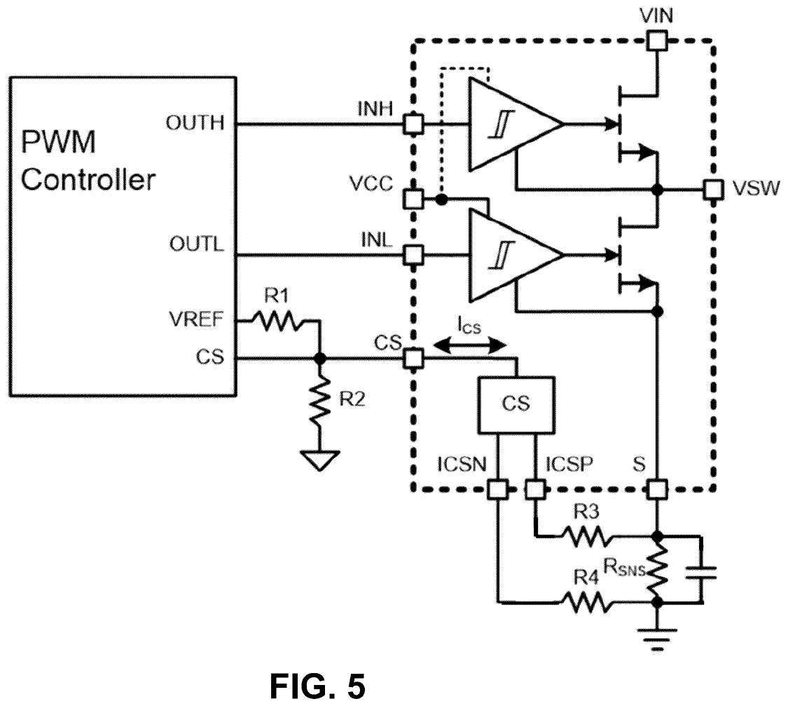

FIG. 5 illustrates a simplified schematic of an integrated power device with bidirectional external current sensing circuit using internal current sense amplifier of the integrated GaN-based die 102, according to some embodiments. In some embodiments, an external current sense resistor can be used while still using the integrated power device's internal amplifier to gain up the voltage across the external sense resistor. Using the internal current sense amplifier to increase the voltage across R_{SNS} can allow for relatively small R_{SNS} values such that the maximum voltage drop can be sized to, for example, +/−100 mV and the power loss in R_{SNS} can be minimized. The internal amplifier may sense the voltage across R_{SNS} through two series resistors, R3 and R4, which can be set to the same value. The voltage at CS is given by:

$${V}_{CS} = {V}_{REF} \frac{{R}_{1}}{{R}_{1} + {R}_{2}} + {I}_{SW} \frac{10 ( {R}_{SNS} )}{{R}_{3 , 4}} \frac{{R}_{1} {R}_{2}}{{R}_{1} + {R}_{2}}$$

In various embodiments, the A/D converter of the PWM controller can sense R_{SNS} directly, however, the max voltage drop across R_{SNS} may be relatively higher to get the resolution used for accurate current sensing. In various embodiments, another external current sensing option can be to add an external amplifier to gain up the R_{SNS} signal and allow for bidirectional current sensing. This technique is similar to FIG. 2 but using an external amplifier instead of the internal amplifier.

### Autonomous Synchronous Rectification

In current approaches, a GaN HEMT may not have a body diode, and thus, the voltage across the HEMT in 3^{rd} quadrant can be, for example, 4 to 5 times that of a comparable Si switch. The resulting conduction losses when the gate remains low can be relatively high, which can eliminate GaN from consideration in power converters using this “freewheel” approaches.

In some embodiments, control methods for autonomous synchronous rectifier (SR) mode enable the power switch to operate as an ideal diode or have reverse channel conduction when the current through the switch is negative (i.e., flowing from the source to the drain). In motor inverter and other applications where reverse current can flow through the power switches, also called “freewheeling”, the voltage across the power switch in combination with the reverse current may create relatively high power dissipation. Circuits and techniques disclosed herein enable driving the power switch as a synchronous rectifier when 3^{rd} quadrant current conduction is detected. In some embodiments, upon detection of significant reverse current in the power switch, the power switch may be turned on, thereby reducing power losses when current flows from the source to the drain. Further, upon approaching zero current (SROFF) the switch can be turned off, autonomously and without the use of a controller.

In various embodiments, a half-bridge circuit operating with an inductive load in buck mode can utilize autonomous synchronous rectification methods. In such embodiments, a control signal for the low-side switch can be kept at zero V, while the high-side control signal can toggle the high-side switch on and off to build current in the load inductor that is connected from the switch node of the half-bridge to ground. Once the high-side switch is turned off, the inductor current commutates to the low-side switch, where the low-side switch can begin to conduct in 3^{rd} quadrant. Once the 3^{rd} quadrant current magnitude in the low-side switch exceeds a predetermined threshold, for example, 700 mA, embodiments of the disclosure enable the integrated power device to autonomously enhance the low-side switch gate terminal (i.e., turn on the gate). The low-side switch gate can be kept enhanced (high) until a high-side “turn-on” control command is received or the current magnitude in the half-bridge decays to a predetermined detection threshold. Anti-shoot through circuitry can ensure that the low-side GaN gate is switched off before a “turn-on” control command is passed to the high-side gate driver. A similar operation technique can work when the high-side switch is in “boost” mode.

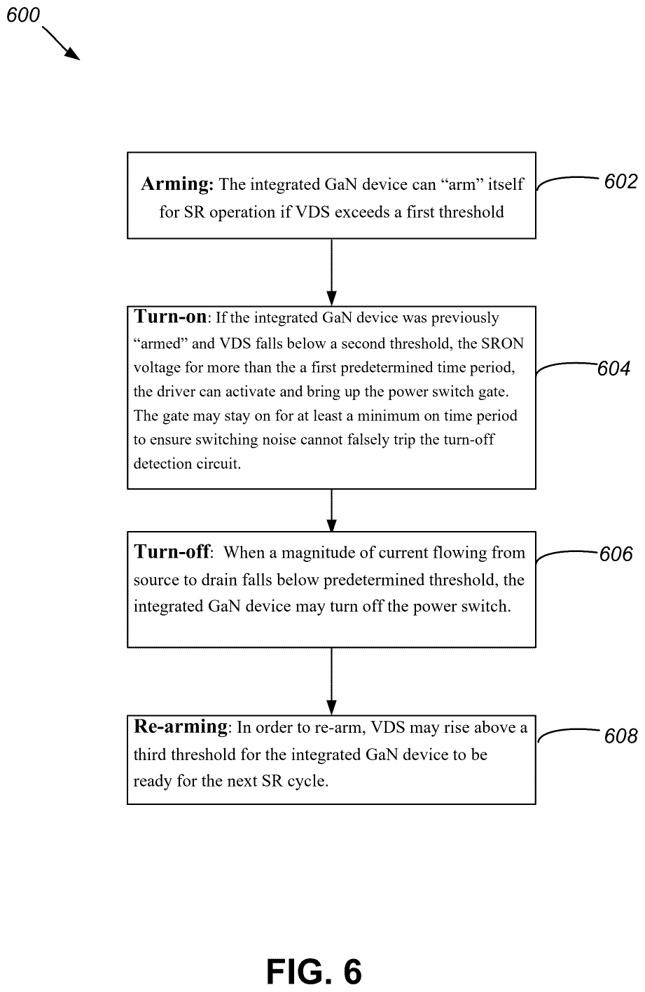

FIG. 6 illustrates a method of activation of the SR functionality, according to some embodiments. FIG. 6 illustrates a method 600 for activation of the SR functionality, the method including arming, where the integrated power device can “arm” itself for SR operation if VDS exceeds a first threshold (602). The method also includes turn-on, where when the integrated power device was previously “armed” and VDS falls below a second threshold (the SRON voltage, e.g. −1.05V) for more than a first predetermined time period, the driver can activate and turn on the power switch (604). The gate may stay on for at least a minimum on-time period to ensure that switching noise cannot falsely trip the turn-off detection circuit. The first predetermined time period can have a value, such as, 50 to 100 ns. In some embodiments the first predetermined time period can be 0.1 to 900 ns, while in other embodiments the first predetermined time period can be 10 to 200 ns.

The method also includes turn-off, where when a magnitude of current flowing from source to drain falls below predetermined threshold, the integrated power device may turn off the power switch (606). The method additionally includes re-arming, where when VDS rises above a third threshold (SRARM voltage, e.g., 9.8V), the integrated power device can become ready for the next SR cycle (608).

It should be appreciated that the specific steps illustrated in FIG. 6 provide a particular method of activation of the SR functionality according to an embodiment of the disclosure. Other sequences of steps may also be performed according to alternative embodiments. For example, alternative embodiments of the disclosure may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

The integrated power device 100 may be arranged to have a programmable synchronous rectifier (SR) mode to allow a power switch to operate as an ideal diode and/or have reverse channel conduction when the current through the switch is negative (flowing from source to drain), according to some embodiments. When the INL or the INH pin is low and if the SR enable pin (SREN) has not been set, then the power switch will be off even when the switch current is negative. If the SREN enable pin has been set and INL or INH is low, then the power switch will turn on if there's negative current flowing through the switch, acting as an ideal diode and increasing the system efficiency.

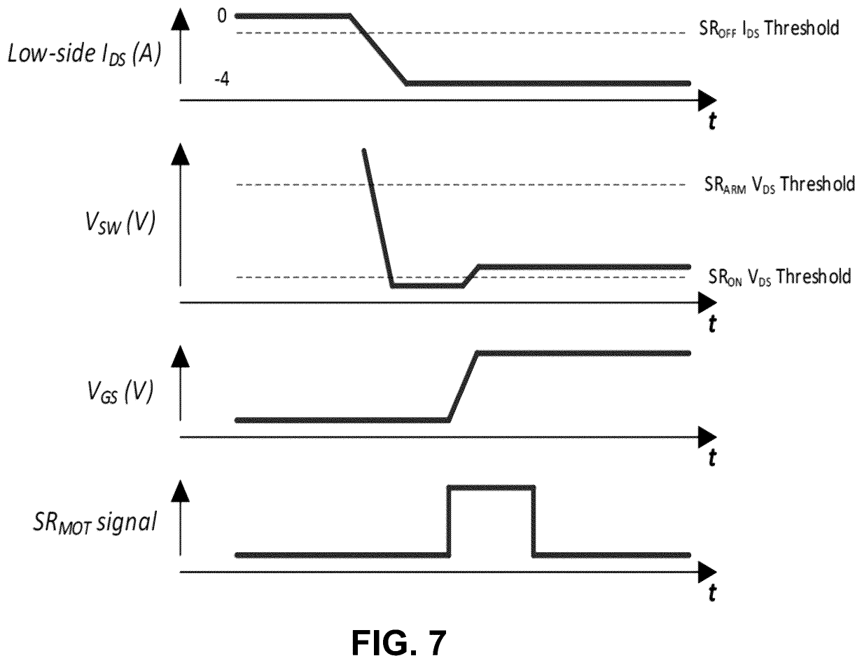

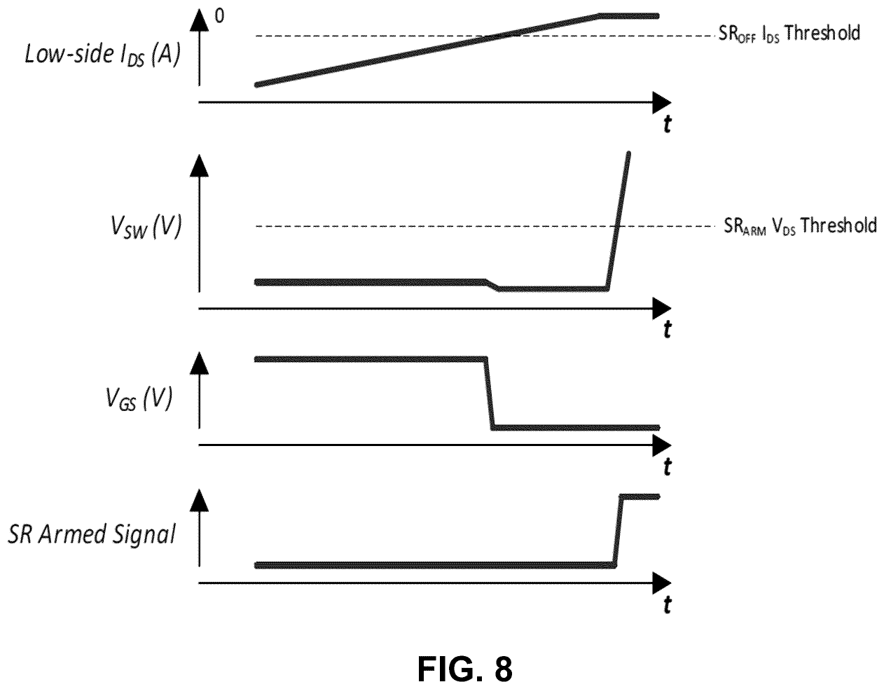

FIG. 7 and FIG. 8 illustrate graphs showing timing diagrams of SR turn on and SR turn off, according to some embodiments.

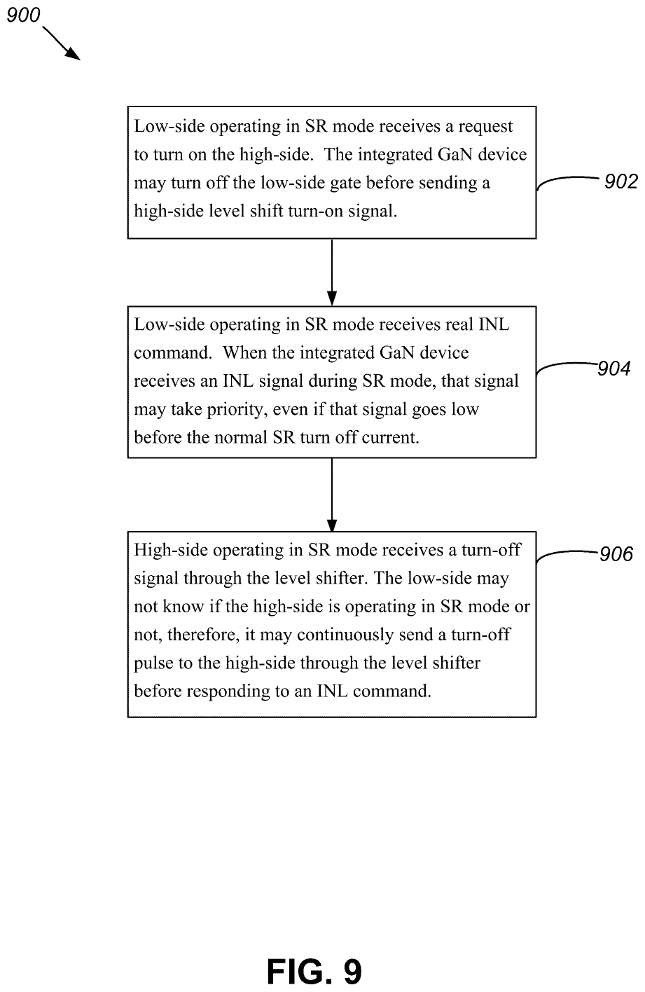

In some embodiments, the autonomous SR mode may include a method of turning off the power switch early, according to some embodiments. FIG. 9 is a simplified flowchart illustrating method 900 for turning off the power switch early in the SR mode, according to some embodiments. As illustrated in FIG. 9, method 900 can include when the low-side operating in SR mode receives a request to turn on the high-side, the integrated power device 100 may turn off the low-side gate before sending a high-side level shift turn-on signal (902). The method can further include when the low-side operating in SR mode receives real INL command, and when the integrated power device 100 receives an INL signal during SR mode, that signal may take priority, even if that signal goes low before the normal SR turn off current (904). The method further includes when the high-side operating in SR mode receives a turn-off signal through the level shifter, the low-side may not know if the high-side is operating in SR mode or not, therefore, it may continuously send a turn-off pulse to the high-side through the level shifter before responding to an INL command (906).

It should be appreciated that the specific steps illustrated in FIG. 9 provide a particular method of turning off the power switch early in the SR mode, according to some embodiments. Other sequences of steps may also be performed according to alternative embodiments. For example, alternative embodiments of the disclosure may perform the steps outlined above in a different order. Moreover, the individual steps illustrated in FIG. 9 may include multiple sub-steps that may be performed in various sequences as appropriate to the individual step. Furthermore, additional steps may be added or removed depending on the particular applications. One of ordinary skill in the art would recognize many variations, modifications, and alternatives.

In some embodiments, SR turn-off may not only have to be with current sensing. Instead of sensing the current falling below a threshold, VSD may be sensed and turn off when that voltage reaches some relatively small value, for example, a few millivolts.

In some embodiments, SR mode can enable accurate negative current sensing using the internal bi-directional sensing method. When current flows in the third quadrant (i.e., from source to drain) and the gate remains low, the ratio of the main power FET to the CS sense FET can be different from when the gate is high. Thus, if the gate stays low, the CS output may have relatively inaccurate gain. Auto SR mode can mitigate this issue by ensuring that the gate turns on and the main FET to CS sense FET ratio is correct when current is negative, even if no PWM signal is present. In current approaches, external CS resistors may not have this issue, since the voltage across them is always just Rcs*Idrn. The disclosed auto SR method can enable “lossless” sensing method in applications where a user doesn't drive the PWM, allowing some users to eliminate the external Rcs without modifying their firmware and/or control scheme.

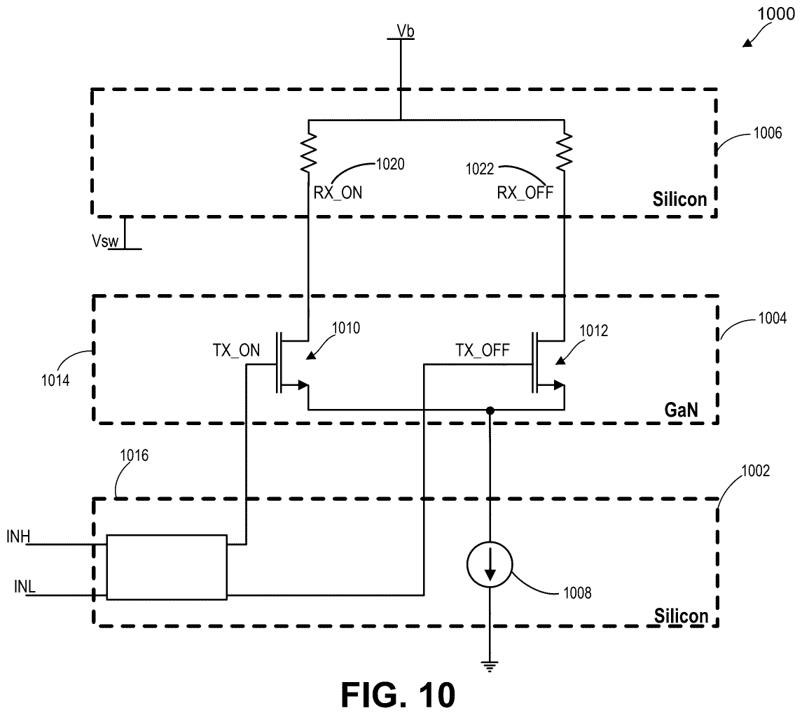

FIG. 10 illustrates a simplified schematic of a level shifter system, according to certain embodiments. As shown in FIG. 10, a level shifter system 1000 may be used in the driver IC used in the integrated power device 100. The level shifter system 1000 may include a transmit circuit 1002, level shifting circuit 1004, and receive circuit 1006. In some embodiments, the transmit circuit 1002 may be references to a low voltage ground, while the receive circuit 1006 may be referenced to a floating voltage. In various embodiments, the transmit circuit 1002 may be formed in silicon, the level shifting switches 1004 formed in GaN and the receive circuit 1006 may be formed in silicon. Level shifting switch circuit 1004 can include a first switch 1010 and a second switch 1012. The first switch 1010 and the second switch 1012 may be formed in a GaN-based die. In some embodiments, the transmit circuit 1002 may be formed on a silicon die, where the transmit circuit die is separate from the receive circuit die. In various embodiments, the transmit circuit 1002 may be formed on the same die as the receive circuit 1006. In some embodiments, the level shifting switches 1004 may be high voltage switches. In various embodiments, the level shifting switches 1004 may be low voltage or mid voltage switches.

By using the same current source 1008 for both receive on (RX_ON) and receive off (RX_OFF) sections, the matching of the network can be further improved as compared to having independent current sources for each level shifting switches 1010 and 1012. By improving the matching in the level shifting circuit, the level shifting circuit can operate with relatively high immunity to false signal propagation. In some embodiments, the current source can be a resistor, or a controlled impedance element. In various embodiments, the current source may be disposed in the GaN die 1014 or on the silicon die 1016.

In some embodiments, the level shifting system 1000 may include a transmit circuit, a receive circuit, first and second level shifting switches where the first and second level shifting switches are formed in gallium nitride (GaN). In various embodiments, the transmit circuit and receive circuit are formed on same die in silicon. In some embodiments, the transmit circuit is formed on a first die, the first and second level shifting switches are formed on a second die, and the receive circuit is formed on a third die, where the first die, second die and third die are co-packaged in a unitary semiconductor package. In various embodiments, the first die and the third die are disposed adjacent on a silicon wafer, where the first die and the third die are picked and placed together in the unitary semiconductor package.

The level shifting circuits and techniques disclosed herein enable forming level shifting circuits used in driver ICs for GaN power devices, where the level shifting circuit operate with relatively high precision allowing power saving. By picking dies from the same silicon wafer for the transmit die and the receive die, a relatively high level of matching can be obtained that enables the level shifting circuit to operate with relatively high accuracy. In some embodiments, a same die may be used for the transmit and receive die by configuring a down-bond (DAP) on the chip that indicates whether the die is used for the transmit or the receive function.

In some embodiments, methods disclosed herein can be used for determining corner operating conditions of the level shifting system 1000 over process and temperature variation spread for the low-side pulse width. In various embodiments, data can be used to determine the slowest dV/dt for which the information of the low-side (LS) may successfully be transmit to the high-side (HS) without any intervention. For example, when the dV/dT is slower than 13V/ns, the LS pulse width may be not guaranteed to get through the level shifter circuit, thus a common mode feedback circuit (CMFB) can be used according to some embodiments. The CMFB circuit can be beneficial because when the rising edge dV/dt is such that (1) the magnitude of the resulting common mode current in the level shift FETs (1004) extends the receive circuit (1006) beyond its operational dynamic range, and (2) the duration of the dV/dt is longer than the current pulse being sent from the transmitter circuit (1002), then without intervention, the signal from the transmitter may be missed by the receiver. Thus, the CMFB circuit can be beneficial to mitigate these operating conditions. The CMFB circuit can sense a common mode current event at the inputs of the receiver and generate output currents through the RX_ON 1020 and RX_OFF 1022 nodes to cancel that current. In this way, the CMFB circuit can bring the receiver inputs back into the proper range for sensing a differential signal, i.e., either a current pulse on 1020 (RX_ON) or on 1022 (RX_OFF). Thus, when the transmitter sends a signal during a dV/dt event that meets the above described two criteria, the signal can still be sensed and acted upon by the receiver.

In some embodiments, combination of the circuits and methods disclosed herein can be utilized to provide bidirectional lossless current sensing and autonomous SR mode operation for integrated power device having a driver circuit and at least a GaN power switch. Although circuits and methods are described and illustrated herein with respect to several particular configuration of operating GaN power switches, embodiments of the disclosure are suitable for operating silicon based and/or silicon carbide-based power switches. Further, circuits and methods described and illustrated herein are suitable for use in AC-DC, DC-DC, ACF, buck, boost, half bridge, full bridge, LLC, AHB, Class D, PFC, motor drive power converters.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “and/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A circuit comprising:
a first switch having a first source terminal and first drain terminal;
a second switch having a second source terminal and second drain terminal, the second drain terminal connected to the first drain terminal and the second source terminal connected to the first source terminal;
wherein the second switch is arranged to generate a first signal corresponding to a current flowing from the first source terminal to the first drain terminal; and
a sensing circuit arranged to receive the first signal and to determine a magnitude and polarity of the current flowing from the first source terminal to the first drain terminal, the sensing circuit further arranged to transmit a second signal based on the first signal.

2. The circuit of claim 1, wherein the first switch is a gallium nitride (GaN)-based switch.

3. The circuit of claim 2, wherein the second switch is a GaN-based switch.

4. The circuit of claim 3, wherein the first and second switches are monolithically formed on single die.

5. The circuit of claim 1, further comprising a third switch having a third source terminal and a third drain terminal, the third source terminal connected to the first drain terminal and to a first terminal of a load, and the third drain terminal connected to a power input node.

6. The circuit of claim 5, further comprising a fourth switch having a fourth source terminal and a fourth drain terminal, the fourth drain terminal connected to the third drain terminal and the fourth source terminal connected to the third source terminal.

7. The circuit of claim 5, wherein the load is a motor.

8. The circuit of claim 1, wherein the first switch and the second switch are formed on a gallium nitride (GaN)-based die and the sensing circuit is formed on a silicon-based die, and wherein the GaN-based die and the silicon-based die are co-packaged in a unitary semiconductor die.

9. The circuit of claim 1, further comprising an overcurrent protection circuit arranged to receive the second signal, compare the second signal to a first threshold and generate a turn off signal when the second signal exceeds the first threshold.

10. A level shifting circuit comprising:
a transmit circuit;
a receive circuit; and
a first level shifting switch and a second level shifting switch; and
wherein the transmit circuit is formed on a first silicon-based die, the receive circuit is formed on a second silicon-based die, and the first and second level shifting switches are formed on a gallium nitride (GaN)-based die.

11. The level shifting circuit of claim 10, wherein the first and second silicon-based die and the GaN-based die are co-packaged in a unitary semiconductor package.

12. The level shifting circuit of claim 10, wherein a source terminal of the first level shifting switch is connected to a source terminal of the second level shifting switch and to a current source.

13. The level shifting circuit of claim 12, wherein the current source is disposed on the first silicon-based die.

14. The level shifting circuit of claim 10, further comprising a common mode feedback circuit.

15. The level shifting circuit of claim 11, wherein during manufacturing the first and second silicon-based die are disposed adjacent on a silicon wafer, and wherein the first and second silicon-based die are picked and co-packaged together in the unitary semiconductor package.

16. A method of operating a circuit, the method comprising:
providing a first switch having a first source terminal and first drain terminal;
providing a second switch having a second source terminal and second drain terminal, the second drain terminal connected to the first drain terminal and the second source terminal connected to the first source terminal;
generating, by the second switch, a first signal corresponding to a current flowing from the first source terminal to the first drain terminal; and
receiving, by a sensing circuit, the first signal; and
determining, by the sense circuit, a magnitude and polarity of the current flowing from the first source terminal to the first drain terminal; and
transmitting, by the sense circuit, a second signal based on the first signal.

17. The method of claim 16, wherein the first and second switches are gallium nitride (GaN)-based switches, and wherein the first and second switches are monolithically formed on single die.

18. The method of claim 16, further comprising providing a third switch having a third source terminal and a third drain terminal, the third source terminal connected to the first drain terminal and to a first terminal of a load, and the third drain terminal connected to a power input node.

19. The method of claim 18, further comprising proving a fourth switch having a fourth source terminal and a fourth drain terminal, the fourth drain terminal connected to the third drain terminal and the fourth source terminal connected to the third source terminal.

20. The method of claim 16, further comprising receiving, by an overcurrent protection circuit, the second signal and comparing the second signal to a first threshold and generating a turn off signal when the second signal exceeds the first threshold.
